(19) United States
(12) Patent Application Publication
(10) Pub. No.: US 2024/0387610 A1
(43) Pub. Date: Nov. 21, 2024

(54) SEMICONDUCTOR ARRANGEMENT AND METHOD OF MAKING

(71) Applicant: TAIWAN SEMICONDUCTOR MANUFACTURING COMPANY LIMITED, Hsin-Chu (TW)

(72) Inventor: Fu-Chiang KUO, Hsinchu City (TW)

(21) Appl. No.: 18/787,593

(22) Filed: Jul. 29, 2024

Related U.S. Application Data
(62) Division of application No. 17/367,698, filed on Jul. 6, 2021.
(60) Provisional application No. 63/166,712, filed on Mar. 26, 2021.

(51) Int. Cl. H01G 4/30

(52) U.S. Cl. CPC H01L 28/60; H01G 4/30

(57) ABSTRACT

A semiconductor arrangement and method of forming the semiconductor arrangement are provided. The semiconductor arrangement includes a first conductive layer and a first dielectric layer over the first conductive layer. A second conductive layer is over a portion of the first dielectric layer and has a sidewall surface. A spacer is over a portion of the sidewall surface of the second conductive layer and covers an interface between the second conductive layer and the first dielectric layer.

### RELATED APPLICATIONS

This application is a divisional of and claims priority to U.S. Non-Provisional patent application Ser. No. 17/367,698, filed on Jul. 6, 2021, which claims priority to U.S. Provisional Patent Application 63/166,712, filed on Mar. 26, 2021. U.S. Non-Provisional patent application Ser. No. 17/367,698 and U.S. Provisional Patent Application 63/166,712 are incorporated herein by reference.

### BACKGROUND

Capacitors are useful to, among other things, store electrical charge within circuits.

### DESCRIPTION OF THE DRAWINGS

Aspects of the disclosure are understood from the following detailed description when read with the accompanying drawings. It will be appreciated that elements and/or structures of the drawings are not necessarily be drawn to scale. Accordingly, the dimensions of the various features may be arbitrarily increased and/or reduced for clarity of discussion.

FIG. 1 is a top view of a semiconductor arrangement, in accordance with some embodiments.

FIG. 2 is a cross-section view of a semiconductor arrangement, in accordance with some embodiments.

FIGS. 3A-3P are cross-section views of a semiconductor arrangement at

various stages of fabrication, in accordance with some embodiments.

FIG. 4 is a flow chart illustrating a method of handling a semiconductor

substrate, in accordance with some embodiments.

FIG. 5 illustrates an example computer-readable medium wherein processor-executable instructions configured to embody one or more of the provisions set forth herein may be comprised, in accordance with some embodiments.

FIG. 6 illustrates an example computing environment wherein one or more of the provisions set forth herein may be implemented, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

One or more techniques for forming a semiconductor arrangement and resulting structures formed thereby are provided herein. According to some embodiments, a capacitor comprises conductive layers and dielectric layers arranged in a stack. In some embodiments, the capacitor is a trench capacitor. Portions of a first conductive layer and a first dielectric layer are removed to expose a second conductive layer under the first conductive layer and the first dielectric layer so that a contact can be formed to contact the second conductive layer. According to some embodiments, during an etch process to remove the first conductive layer and the first dielectric layer, a precursor gas is added to the etch mixture to cause a spacer to form on sidewalls of the first conductive layer. In some embodiments, the precursor gas comprises a halogen gas, and the spacer formed during the etch process comprises a metal halide material. The spacer covers and protects the sidewall of the first conductive layer at an interface where the first conductive layer contacts the first dielectric layer to reduce erosion of the first dielectric layer during the etch process or a subsequent process, such as an ashing process and/or a cleaning process. In some embodiments, the spacer covers and protects the sidewall of the first conductive layer at a first interface where the first conductive layer contacts the first dielectric layer under the first conductive layer and at a second interface where the first conductive layer contacts a second dielectric layer over the first conductive layer. Reducing erosion of the dielectric material (e.g., the first dielectric layer and/or the second dielectric layer) reduces leakage current, increases capacitance of the capacitor, and reduces defects in the capacitor, such as a short between the first conductive layer and the second conductive layer.

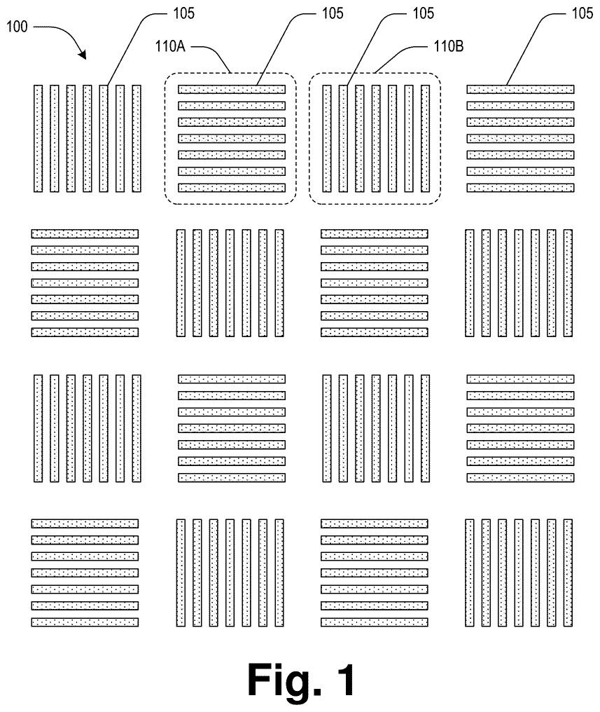

FIG. 1 is a top view illustrating a portion of a semiconductor arrangement 100 according to some embodiments. In some embodiments, the semiconductor arrangement 100 comprises capacitors 105, such as trench capacitors, arranged in groups 110A, 110B. In some embodiments, the groups 110A, 110B are arranged in a grid format, where adjacent groups 110A, 110B are rotated 90 degrees with respect to one another. Material formed in a trench can exert stress on structures adjacent the trench. Providing the groups 110A, 110B with different orientations results in the stress being directed in different directions, thereby reducing the likelihood of warping occurring on a substrate layer on which the capacitors 105 are formed.

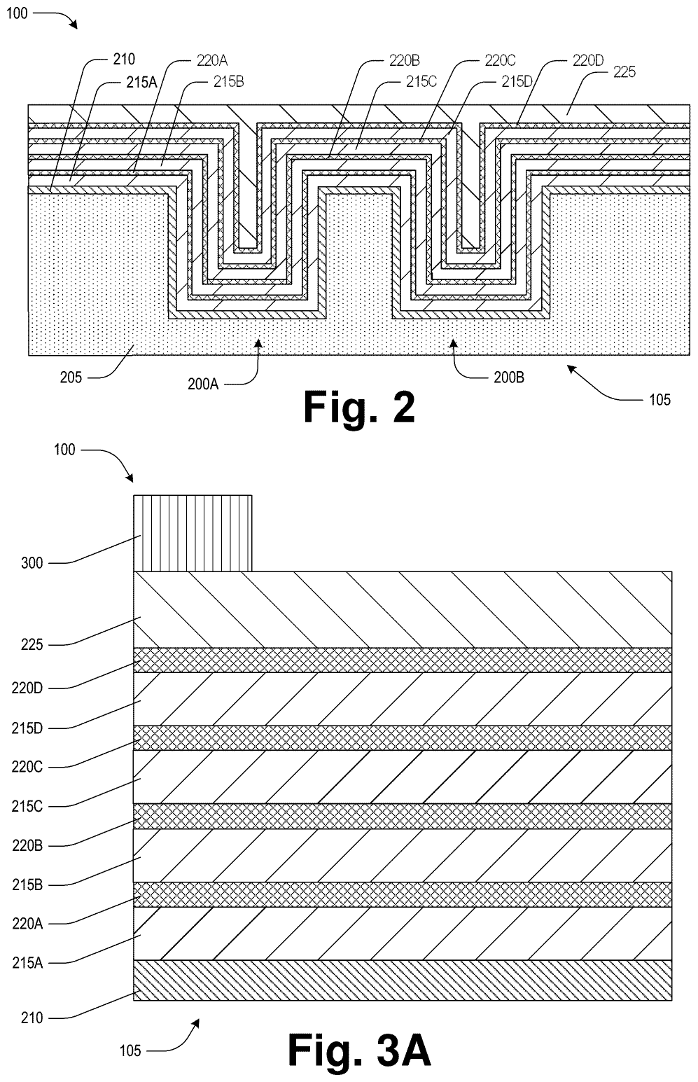

Referring to FIG. 2, a cross section view of the semiconductor arrangement 100 is provided. In some embodiments, the capacitor 105 is formed in trenches 200A, 200B formed in a substrate layer 205. In some embodiments, the substrate layer 205 comprises at least one of an epitaxial layer, a single crystalline semiconductor material, such as, but not limited to, at least one of Si, Ge, SiGe, InGaAs, GaAs, InSb, GaP, GaSb, InAlAs, GaSbP, GaAsSb, or InP, a silicon-on-insulator (SOI) structure, a wafer, or a die formed from a wafer. In some embodiments, the substrate layer 205 comprises at least one of crystalline silicon or other suitable materials. Other structures and/or configurations of the substrate layer 205 are within the scope of the present disclosure.

In an embodiment, the trenches 200A, 200B are formed in the substrate layer 205. In some embodiments, the trenches 200A, 200B are formed by forming at least one mask layer over the substrate layer 205. In some embodiments, the mask layer comprises a layer of oxide material over the substrate layer 205, a layer of nitride material over the layer of oxide material, and/or one or more other suitable layers. At least some of the material of the mask layer is removed to define an etch mask for use as an etch template to etch the substrate layer 205 to form the trenches 200A, 200B. The number of trenches 200A, 200B formed in the substrate layer 205 may vary. In the illustration of FIG. 2, the capacitor 105 is formed in two trenches in the substrate layer 205. Other structures and configurations of the capacitor 105 are within the scope of the present disclosure. For example, any number of trenches 200A, 200B may be employed to form a single capacitor 105 or a group 110A, 110B of capacitors 105.

Referring to FIG. 2, the capacitor 105 is formed by forming a dielectric layer 210 in the trenches 200A, 200B. In some embodiments, the dielectric layer 210 comprises silicon dioxide, silicon nitride, or other suitable dielectric materials. In some embodiments, the dielectric layer 210 is formed by at least one of atomic layer deposition (ALD), chemical vapor deposition (CVD), low pressure CVD (LPCVD), atomic layer chemical vapor deposition (ALCVD), ultrahigh vacuum CVD (UHVCVD), reduced pressure CVD (RPCVD), or other suitable techniques. In some embodiments, the dielectric layer 210 electrically isolates the capacitor 105 from the substrate layer 205.

According to some embodiments, a conductive layer 215A is formed over the dielectric layer 210. In some embodiments, the conductive layer 215A comprises a conductive material, such as titanium (Ti), titanium nitride (TiN), tantalum (Ta), tantalum nitride (TaN), tantalum carbide (TaC), tungsten (W), iridium (Ir), rubidium (Ru), platinum (Pt), aluminum (Al), copper (Cu), and/or other suitable materials or combinations of suitable materials. In some embodiments, the conductive layer 215A is formed by at least one of ALD, PVD, CVD, thermal evaporation, and/or other suitable techniques.

In some embodiments, a dielectric layer 220A is formed over the conductive layer 215A. In some embodiments, the dielectric layer 220A comprises a high-k dielectric material. As used herein, the term “high-k dielectric” refers to the material having a dielectric constant, k, greater than or equal to about 3.9, which is the k value of SiO₂. The high-k dielectric material may be any suitable material. Examples of the high-k dielectric material include but are not limited to Al₂O₃, HfO₂, ZrO₂, La₂O₃, TiO₂, SrTiO₃, LaAlO₃, Y₂O₃, Al₂OₓN_{y}, HfOₓN_{y}, ZrOₓN_{y}, La₂OₓN_{y}, TiOₓN_{y}, SrTiOₓN_{y}, LaAlOₓN_{y}, Y₂OₓN_{y}, SiON, SiNₓ, a silicate thereof, and an alloy thereof. Each value of x is independently from 0.5 to 3, and each value of y is independently from 0 to 2. According to some embodiments, the dielectric layer 220A is formed by thermal growth, chemical growth, ALD, CVD, plasma-enhanced chemical vapor deposition (PECVD), and/or other suitable techniques.

According to some embodiments, a conductive layer 215B is formed over the dielectric layer 220A, a dielectric layer 220B is formed over the conductive layer 215B, a conductive layer 215C is formed over the dielectric layer 220B, a dielectric layer 220C is formed over the conductive layer 215C, a conductive layer 215D is formed over the dielectric layer 220C, and a dielectric layer 220D is formed over the conductive layer 215D. In some embodiments, a dielectric layer 225 is formed over the dielectric layer 220D to fill the trenches and extend above the upper surface of the dielectric layer 220D.

In some embodiments, the conductive layers 215A, 215B, 215C, 215D have the same material composition. In some embodiments, a thickness of the conductive layers 215A, 215B, 215C, 215D is approximately the same. In some embodiments, the material composition of at least one of the conductive layers 215A, 215B, 215C, 215D may be different than the material composition of another at least one of the conductive layers 215A, 215B, 215C, 215D and/or the thickness of at least one of the conductive layers 215A, 215B, 215C, 215D may be different than may be different than the thickness of another at least one of the conductive layers 215A, 215B, 215C, 215D. The material composition and/or thickness of the conductive layers 215A, 215B, 215C, 215D may be selected based upon, among other things, specified parameters, such as capacitance of the capacitor 105. In some embodiments, the thickness of one of the conductive layers 215A, 215B, 215C, 215D is between about 100 and 300 angstroms. In some embodiments, the thickness of one of the conductive layers 215A, 215B, 215C, 215D is about 200 angstroms. In some embodiments, the dielectric layers 220A, 220B, 220C, 220D have the same material composition. In some embodiments, a thickness of the dielectric layers 220A, 220B, 220C, 220D is approximately the same. In some embodiments, the thickness of one of the dielectric layers 220A, 220B, 220C, 220D is about between about 40 and 100 angstroms. In some embodiments, the thickness of one of the dielectric layers 220A, 220B, 220C, 220D is about 70 angstroms. In some embodiments, the material composition of at least one of the dielectric layers 220A, 220B, 220C, 220D may be different than the material composition of another at least one of the dielectric layers 220A, 220B, 220C, 220D and/or the thickness of at least one of the dielectric layers 220A, 220B, 220C, 220D may be different than may be different than the thickness of another at least one of the dielectric layers 220A, 220B, 220C, 220D. The material composition and/or thickness of the dielectric layers 220A, 220B, 220C, 220D may be selected based upon, among other things, specified parameters, such as capacitance of the capacitor 105.

In some embodiments, the capacitor 105 includes five trenches 200A, 200B and occupies a space of about 100 micrometers. In some embodiments, an aspect ratio of the trenches 200A, 200B is about 1:5 or higher. In some embodiments, the number of conductive layers 215A, 215B, 215C, 215D and dielectric layers 220A, 220B, 220C, 220D in the capacitor 105 varies. In some embodiments, the capacitor 105 comprises at least two conductive layers 215A, 215B, 215C, 215D and at least two dielectric layers 220A, 220B, 220C, 220D.

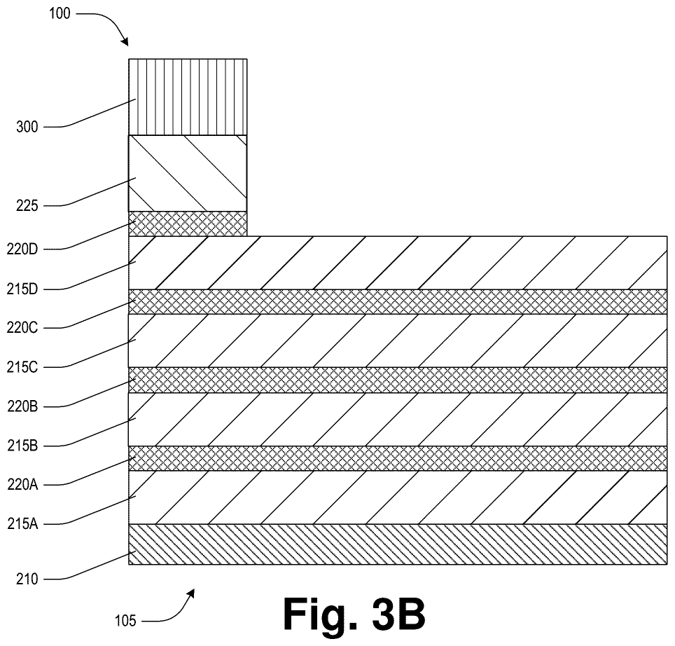

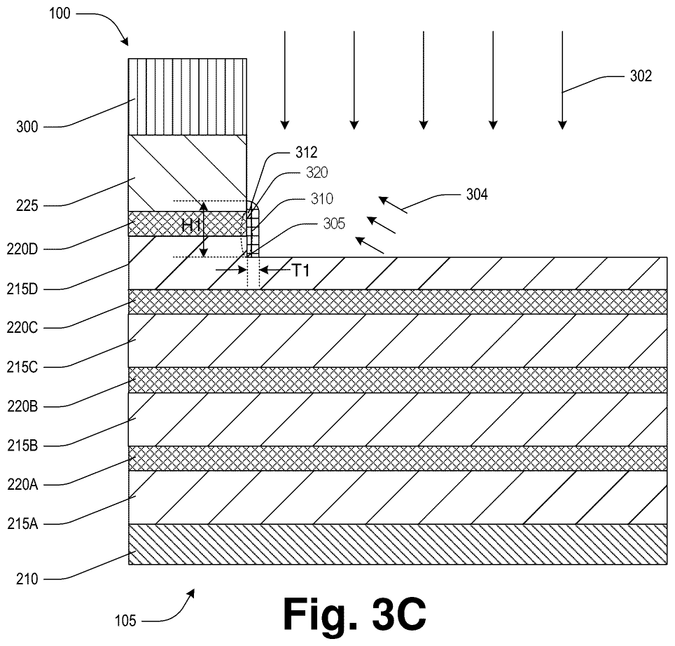

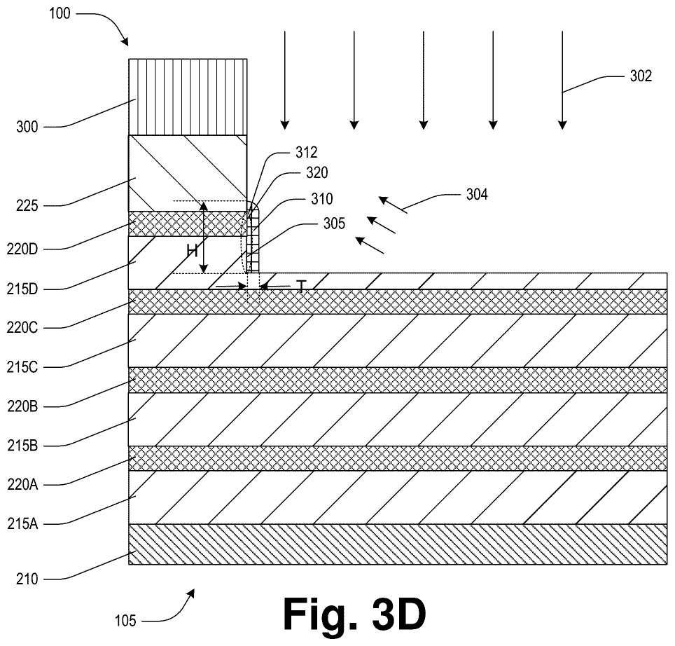

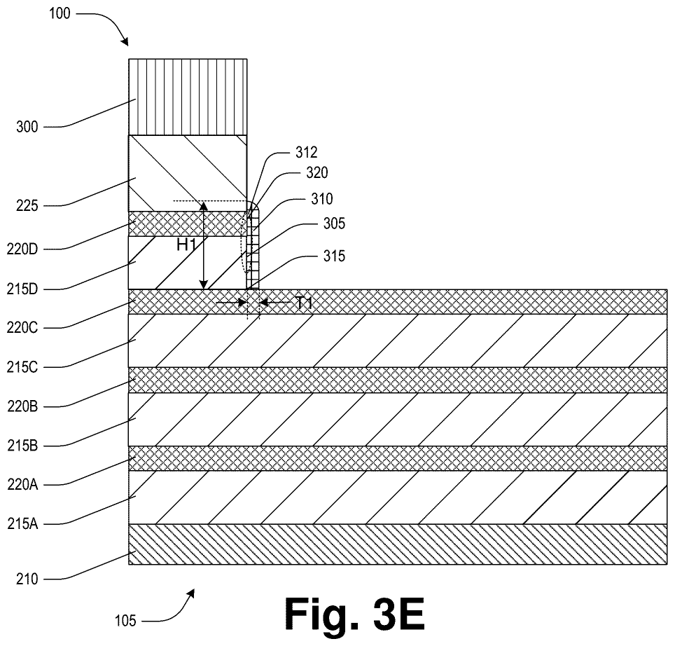

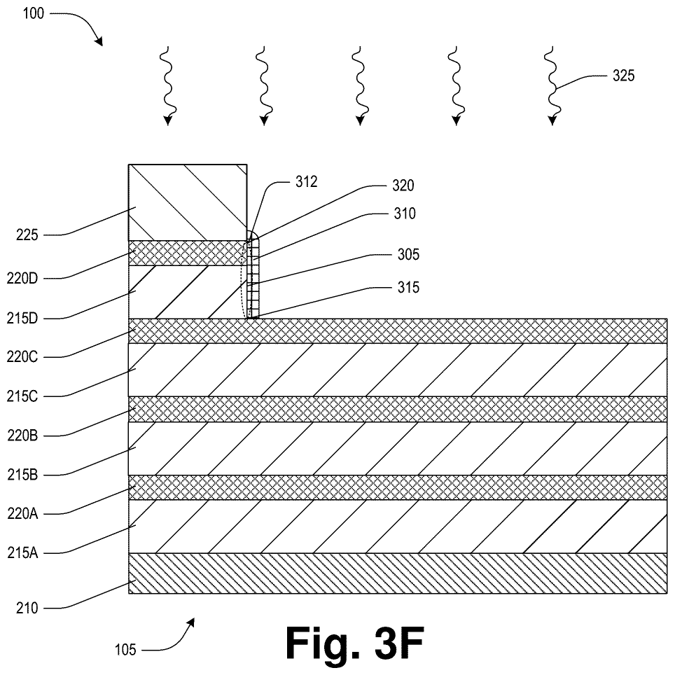

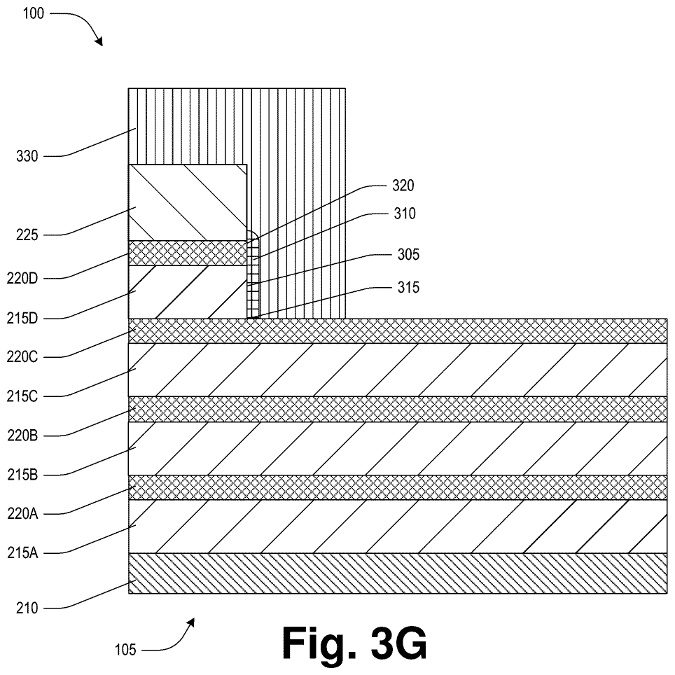

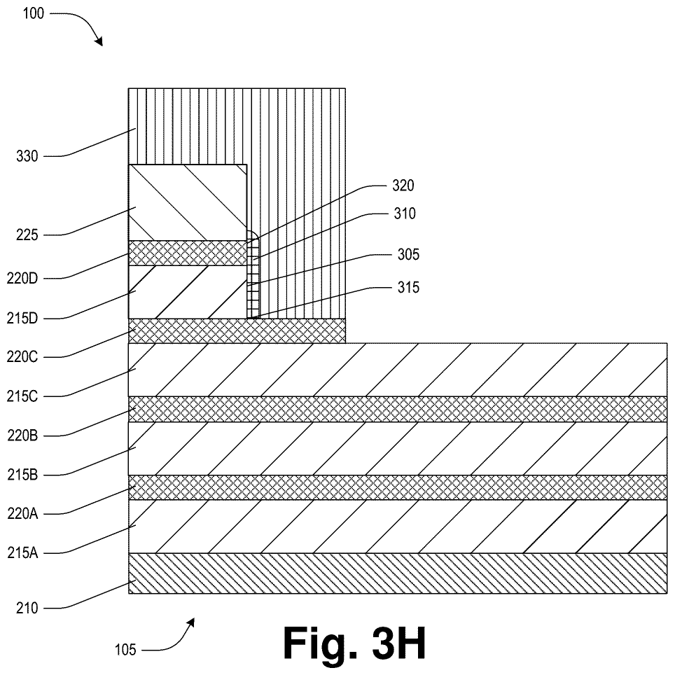

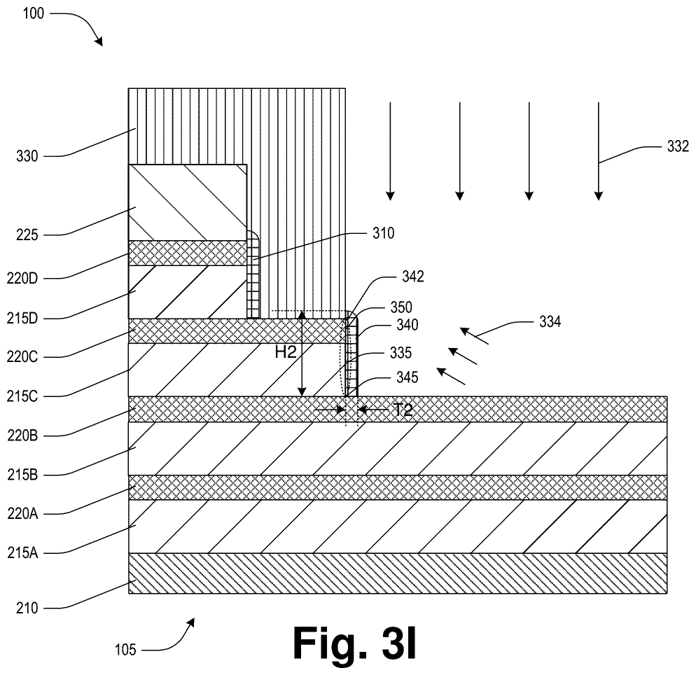

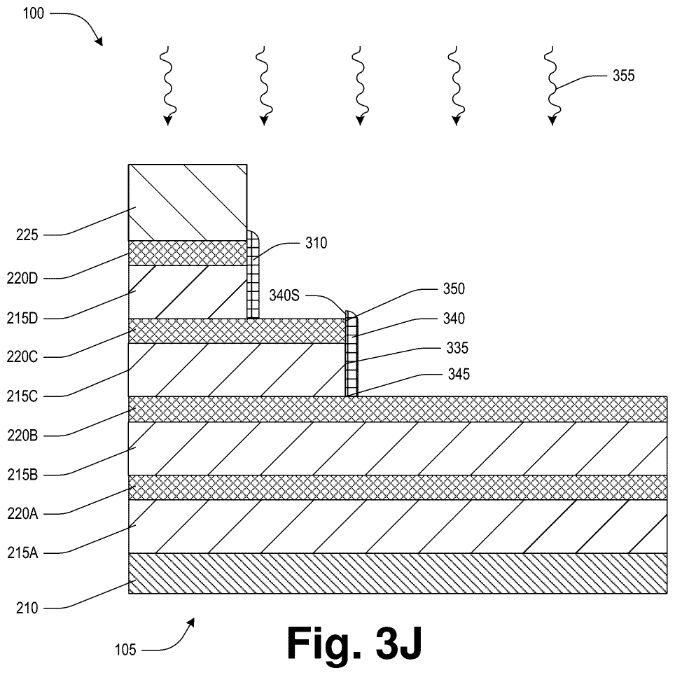

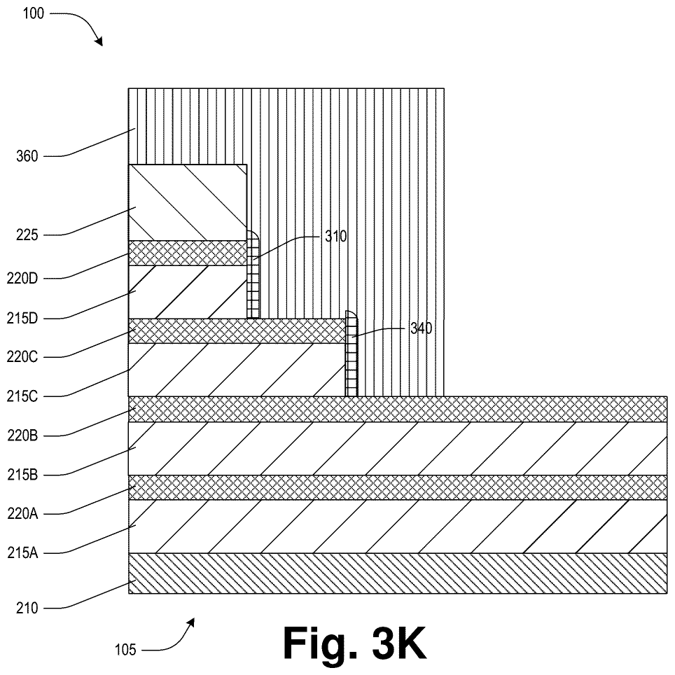

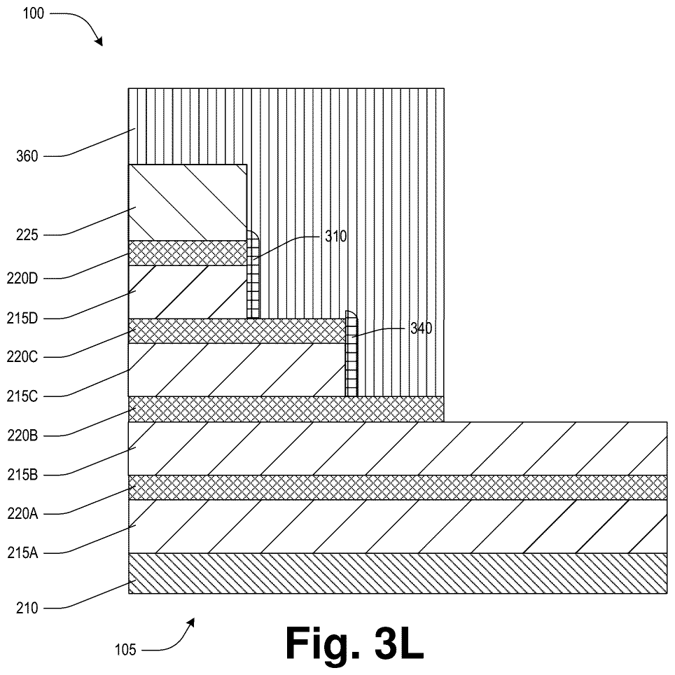

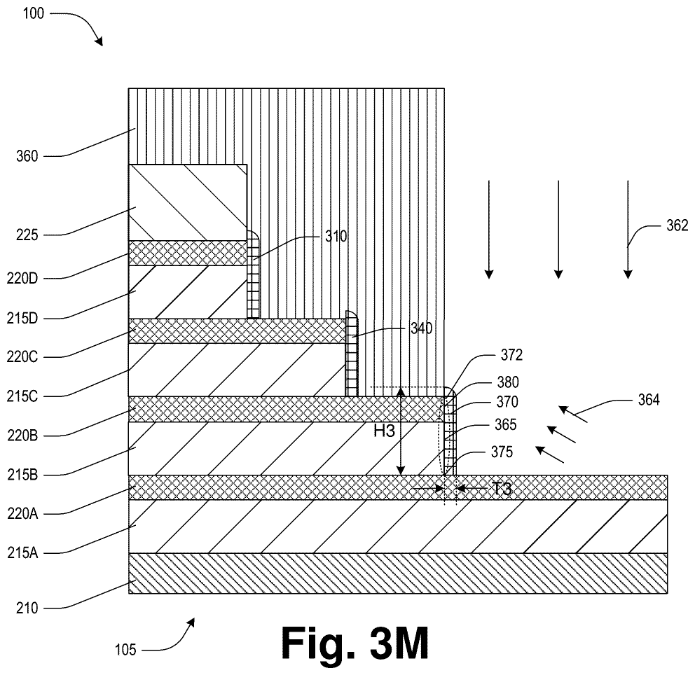

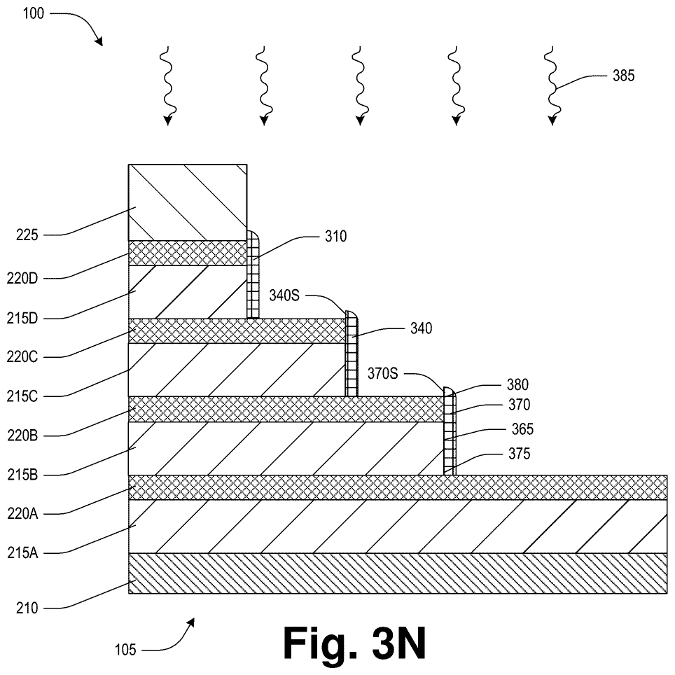

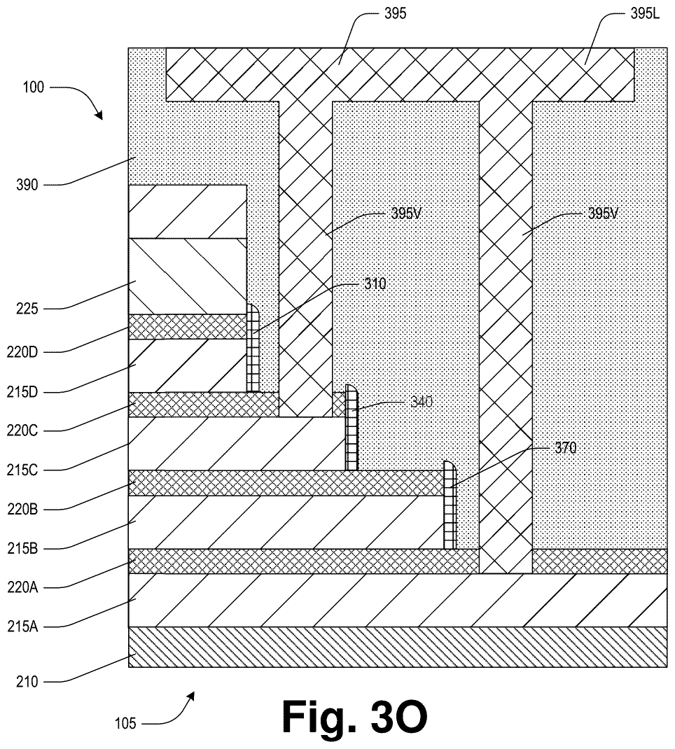

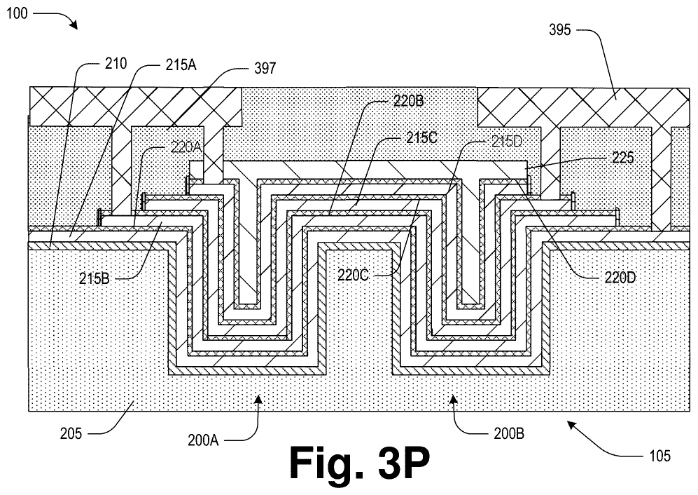

FIGS. 3A-3P are cross-section views of the semiconductor arrangement 100 at various stages of fabrication, in accordance with some embodiments. Referring to FIG. 3, a portion of the capacitor 105 over a horizontal portion of the dielectric layer 210 and adjacent the trenches 200A, 200B is illustrated.

Referring to FIG. 3A, a mask 300 is formed over the dielectric layer 225, according to some embodiments. In some embodiments, the mask 300 comprises a photoresist layer. In some embodiments, the photoresist layer is formed by at least one of spinning, spray coating, or other suitable techniques. The photoresist is a negative photoresist or a positive photoresist. With respect to a negative photoresist, regions of the negative photoresist become insoluble when illuminated by a light source, such that application of a solvent to the negative photoresist during a subsequent development stage removes non-illuminated regions of the negative photoresist. A pattern formed in the negative photoresist is thus a negative image of a pattern defined by opaque regions of a template, such as a mask, between the light source and the negative photoresist. In a positive photoresist, illuminated regions of the positive photoresist become soluble and are removed via application of a solvent during development. Thus, a pattern formed in the positive photoresist is a positive image of opaque regions of the template, such as a mask, between the light source and the positive photoresist. One or more etchants have a selectivity such that the one or more etchants remove or etch away one or more layers exposed or not covered by the photoresist at a greater rate than the one or more etchants remove or etch away the photoresist. Accordingly, an opening in the photoresist allows the one or more etchants to form a corresponding opening in the one or more layers under the photoresist, and thereby transfer a pattern in the photoresist to the one or more layers under the photoresist. The photoresist is ashed, stripped, or washed away after the pattern transfer.

Referring to FIG. 3B, the mask 300 is used as an etch template to remove exposed portions of the dielectric layer 225 and the dielectric layer 220D, according to some embodiments. In some embodiments, one or more etch processes are performed using etch chemistries that remove the material of the dielectric layer 225 and the dielectric layer 220D to expose the conductive layer 215D. In some embodiments, the conductive layer 215D is an etch stop layer for the etch process that removes the dielectric layer 220D.

Referring to FIGS. 3C, 3D, and 3E, the mask 300 is used as an etch template to remove exposed portions of the conductive layer 215D, according to some embodiments. In some embodiments, an etch process 302 is performed using an etch chemistry that removes the material of the conductive layer 215D. In some embodiments, the etch process comprises a reactive ion etch using a carbon tetrafluoride (CF₄) etch gas or other suitable etch gas. In some embodiments, a precursor gas comprising a halogen is added to the etch gas during at least one phase of the etch process 302. In some embodiments, the halogen comprises at least one of fluorine, chlorine, bromine, or another suitable material. FIGS. 3C, 3D, and 3E show the etch process 302 as the etch front progresses through the conductive layer 215B. According to some embodiments, the halogen reacts with material of the conductive layer 215D during the etch process to form a metal halide material that deposits on a portion of the sidewall surface 305 of the conductive layer 215D to form a spacer 310. As used herein the language regarding covering “a portion” of a sidewall surface includes covering the entire sidewall surface. In an embodiment where the material of the conductive layer 215D is TiN and the halogen precursor gas is fluorine, the spacer 310 comprises the metal halide, titanium tetrafluoride (TiF₄). The spacer 310 can comprise other metal halide materials if different conductive materials and/or halogen precursor gases are used. In some embodiments, the metal halide formed during the etch process 302 has a sublimation point or boiling point of at least around 130°° C. to 230° C. In some embodiments, a portion of the metal halide generated during the etch process is volatile and is exhausted from the etch chamber. However, the etch process 302 also includes a redepositing component 304, where a portion of the metal halide is sputtered during the etch process 302 and deposits on the sidewall surface 305 of the conductive layer 215D to form the spacer 310. In some embodiments, the dielectric layer 220C is an etch stop layer for the etching of the conductive layer 215D.

In some embodiments, the spacer 310 covers a sidewall interface 312 defined by the sidewall surface 305 of the conductive layer 215D and a sidewall surface 320 of the dielectric layer 220D. In some embodiments, the height H1 and/or thickness T1 of the spacer 310 are controlled by the ratio of halogen gas to etching gas. Increasing the amount of halogen gas increases the amount of metal halide material that forms and deposits during the redepositing component 304 to form the spacer 310. In some embodiments, the spacer 310 covers a portion of a sidewall surface of the dielectric layer 220C. Referring to FIG. 3E, after the completion of the etch process 302, the spacer 310 covers a corner interface 315 defined where the conductive layer 215D contacts an upper surface of the dielectric layer 220C. In some embodiments, the thickness, T1, of the spacer 310 is between about 0.3 and 0.7 micrometers. In some embodiments, the thickness, T1, of the spacer 310 is 0.5 micrometers or less.

Referring to FIG. 3F, the mask 300 is removed according to some embodiments. In some embodiments, the mask 300 is removed by performing a removal process 325. In some embodiments, the removal process 325 comprises an oxygen plasma strip process. In some embodiments, the removal process 325 also includes a cleaning process, such as a diluted hydrofluoric acid (DHF) wet cleaning process, to remove residue from the oxygen plasma strip process. The spacer 310 protects the dielectric layers 220C, 220D from erosion during the removal process 325 at the corner interface 315 and the sidewall interface 312, respectively. In some embodiments, a portion of the spacer 310 is removed during the removal process 325, and the height H1 and/or the thickness T1 may be reduced.

Referring to FIG. 3G, a mask 330 is formed over the dielectric layer 225, the dielectric layer 220D, the conductive layer 215D, the spacer 310, and a portion of the dielectric layer 220C, according to some embodiments. In some embodiments, the mask 330 comprises a photoresist layer. In some embodiments, the photoresist layer is formed by at least one of spinning, spray coating, or other suitable techniques. The photoresist is patterned using a positive or negative technique to form the mask 330.

Referring to FIG. 3H, the mask 330 is used as an etch template to remove exposed portions of the dielectric layer 220C, according to some embodiments. In some embodiments, an etch process is performed using an etch chemistry that removes the material of the exposed portions of the dielectric layer 220C to expose the conductive layer 215C. In some embodiments, the conductive layer 215C is an etch stop layer for the etch process that removes the dielectric layer 220C.

Referring to FIG. 3I, the mask 330 is used as an etch template to remove exposed portions of the conductive layer 215C, according to some embodiments. In some embodiments, an etch process 332 is performed using an etch chemistry that removes the material of the conductive layer 215C. In some embodiments, the etch process 332 comprises a reactive ion etch using a carbon tetrafluoride (CF₄) etch gas or other suitable etch gas. In some embodiments, a precursor gas comprising a halogen is added to the etch gas during at least one phase of the etch process 332. In some embodiments, the halogen comprises at least one of fluorine, chlorine, bromine, or another suitable material. In some embodiments, the halogen in the precursor gas for the etch process 332 is the same halogen used for the etch process 302. In some embodiments, a different halogen is used in the etch process 332. According to some embodiments, the halogen reacts with material of the conductive layer 215C during the etch process 332 to form a metal halide material that deposits on a sidewall surface 335 of the conductive layer 215C to form a spacer 340. In some embodiments, the etch process 332 includes a redepositing component 334, where a portion of the metal halide is sputtered during the etch process 332 and deposits on the sidewall surface 335 of the conductive layer 215C to form the spacer 340. In some embodiments, the dielectric layer 220B is an etch stop layer for the etching of the conductive layer 215C. The etch process 332 progresses as illustrated in FIGS. 3C-3E to form the spacer 340.

In some embodiments, the spacer 340 covers at least a portion of the sidewall surface 335 of the conductive layer 215C at a corner interface 345 where the conductive layer 215C contacts an upper surface of the dielectric layer 220B. In some embodiments, the spacer 340 covers a sidewall interface 342 defined by the sidewall surface 335 of the conductive layer 215C and a sidewall surface 350 of the dielectric layer 220C. In some embodiments, the spacer 340 covers a portion of a sidewall surface of the mask 330. In some embodiments, the height H2 and/or thickness T2 of the spacer 340 are controlled by the ratio of halogen gas to etching gas. Increasing the amount of halogen gas increases the amount of metal halide material that forms and deposits to form the spacer 340. In some embodiments, the thickness, T2, of the spacer 310 is between about 0.3 and 0.7 micrometers. In some embodiments, the thickness, T2, of the spacer 310 is 0.5 micrometers or less.

Referring to FIG. 3J, the mask 330 is removed according to some embodiments. In some embodiments, the mask 330 is removed by performing a removal process 355. In some embodiments, the removal process 355 comprises an oxygen plasma strip process. In some embodiments, the removal process 355 also includes a cleaning process, such as a DHF wet cleaning process, to remove residue from the oxygen plasma strip process. The spacer 340 protects the dielectric layers 220B, 220C from erosion during the removal process 355. In some embodiments, after removal of the mask 330, a portion of a sidewall surface 340S of the spacer 340 is exposed. In some embodiments, a portion of the spacer 340 is removed during the removal process 355, and the height H2 and/or the thickness T2 may be reduced.

Referring to FIG. 3K, a mask 360 is formed over the dielectric layer 225, the dielectric layers 220C, 220D, the conductive layers 215C, 215D, the spacers 310, 340 and a portion of the dielectric layer 220B, according to some embodiments. In some embodiments, the mask 360 comprises a photoresist layer. In some embodiments, the photoresist layer is formed by at least one of spinning, spray coating, or other suitable techniques. The photoresist is patterned using a positive or negative technique to form the mask 360.

Referring to FIG. 3L, the mask 360 is used as an etch template to remove exposed portions of the dielectric layer 220B, according to some embodiments. In some embodiments, an etch process is performed using an etch chemistry that removes the material of the exposed portions of the dielectric layer 220B to expose the conductive layer 215B. In some embodiments, the conductive layer 215B is an etch stop layer for the etch process that removes the dielectric layer 220B.

Referring to FIG. 3M, the mask 360 is used as an etch template to remove exposed portions of the conductive layer 215B, according to some embodiments. In some embodiments, an etch process 362 is performed using an etch chemistry that removes the material of the conductive layer 215B. In some embodiments, the etch process 362 comprises a reactive ion etch using a carbon tetrafluoride (CF₄) etch gas or other suitable etch gas. In some embodiments, a precursor gas comprising a halogen is added to the etch gas during at least one phase of the etch process 362. In some embodiments, the halogen comprises at least one of fluorine, chlorine, bromine, or another suitable material. In some embodiments, the halogen in the precursor gas for the etch process 362 is the same halogen used for the etch process 302 or the etch process 332. In some embodiments, a different halogen is used in the etch process 362 compared to the halogen(s) used in the etch processes 302, 332. According to some embodiments, the halogen reacts with material of the conductive layer 215B during the etch process 362 to form a metal halide material that deposits on a sidewall surface 365 of the conductive layer 215B to form a spacer 370. In some embodiments, the etch process 332 includes a redepositing component 364, where a portion of the metal halide is sputtered during the etch process 362 and deposits on the sidewall surface 365 of the conductive layer 215B to form the spacer 370. In some embodiments, the dielectric layer 220A is an etch stop layer for the etching of the conductive layer 215B.

In some embodiments, the spacer 370 covers at least a portion of the sidewall surface 365 of the conductive layer 215B at a corner interface 375 where the conductive layer 215B contacts an upper surface of the dielectric layer 220A. In some embodiments, the spacer 370 covers a sidewall interface 372 defined by the sidewall surface 365 of the conductive layer 215B and a sidewall surface 380 of the dielectric layer 220B. In some embodiments, the spacer 370 covers a portion of a sidewall surface of the mask 360. In some embodiments, the height H3 and/or thickness T3 of the spacer 370 is controlled by the ratio of halogen gas to etching gas. Increasing the amount of halogen gas increases the amount of metal halide material that forms and deposits to form the spacer 340. In some embodiments, the thickness, T3, of the spacer 310 is between about 0.3 and 0.7 micrometers. In some embodiments, the thickness, T3, of the spacer 310 is 0.5 micrometers or less.

Referring to FIG. 3N, the mask 360 is removed according to some embodiments. In some embodiments, the mask 360 is removed by performing a removal process 385. In some embodiments, the removal process 385 comprises an oxygen plasma strip process. In some embodiments, the removal process 385 also includes a cleaning process, such as a DHF wet cleaning process, to remove residue from the oxygen plasma strip process. The spacer 370 protects the dielectric layers 220A, 220B from erosion during the removal process 385. In some embodiments, after removal of the mask 360, the portion of the sidewall surface 370S of the spacer 370 and a portion of a sidewall surface 370S of the spacer 370 are exposed. In some embodiments, a portion of the sidewall spacer 380 is removed during the removal process 385, and the height H3 and/or the thickness T3 may be reduced.

Referring to FIG. 3O, a dielectric layer 390 is formed over the capacitor 105 and an interconnect structure 395 is formed in the dielectric layer 390, according to some embodiments. In some embodiments, the interconnect structure 395 comprises a line portion 395L and a via portion 395V. In some embodiments, the interconnect structure 395 is formed in any number of ways, such as by a single damascene process, a dual damascene process, a trench silicide process, and/or other suitable techniques. In some embodiments, additional contacts (not shown) are formed to contact the capacitor 105 at different positions, such as into or out of the page or to the left of the portion of the capacitor 105 illustrated in FIG. 3O. In some embodiments, the interconnect structure 395 comprises a barrier layer, a seed layer, a metal fill layer, and/or other suitable layers. In some embodiments, the metal fill layer comprises tungsten, aluminum, copper, cobalt, and/or other suitable materials. Other structures and/or configurations of the interconnect structure 395 are within the scope of the present disclosure. In some embodiments, the via portions 395V of the interconnect structure 395 contact the conductive layers 215A, 215C.

FIG. 3P illustrates the semiconductor arrangement 100 after the processing of FIGS. 3A-3O, according to some embodiments. In some embodiments, an interconnect structure 397 is formed on the side of the capacitor 105 opposite the interconnect structure 395. In some embodiments, the interconnect structure contacts the conductive layers 215B, 215D. The configuration of the interconnect structures 395, 397 depends on the interconnections between the conductive layers 215A, 215B, 215C, 215D to form the capacitor. For example, to form a set of parallel capacitors in the capacitor 105, a power supply voltage, V_{DD}, is applied to the conductive layers 215A, 215C using the interconnect structure 395 and a reference supply voltage, V_{SS}, is applied to the conductive layers 215B, 215D using the interconnect structure 397.

To form a set of series capacitors in the capacitor 105, the power supply voltage, V_{DD}, is applied to the conductive layer 215A and the reference supply voltage, V_{SS}, is applied to the conductive layer 215D. For example, the via of the interconnect structure 395 contacting the conductive layer 215C may be omitted, the via of the interconnect structure 397 contacting the conductive layer 215B may be omitted, V_{DD} may be applied to the interconnect structure 397, and V_{SS} may be applied to the interconnect structure 395. Thus, embodiments where a set of series capacitors are to be formed, interconnect structures may be provided that connect to the conductive layers 215A, 215D to provide the V_{DD} and V_{SS} voltages, respectively (instead of connecting a single interconnect structure to the conductive layers 215A, 215C as shown in FIG. 3O).

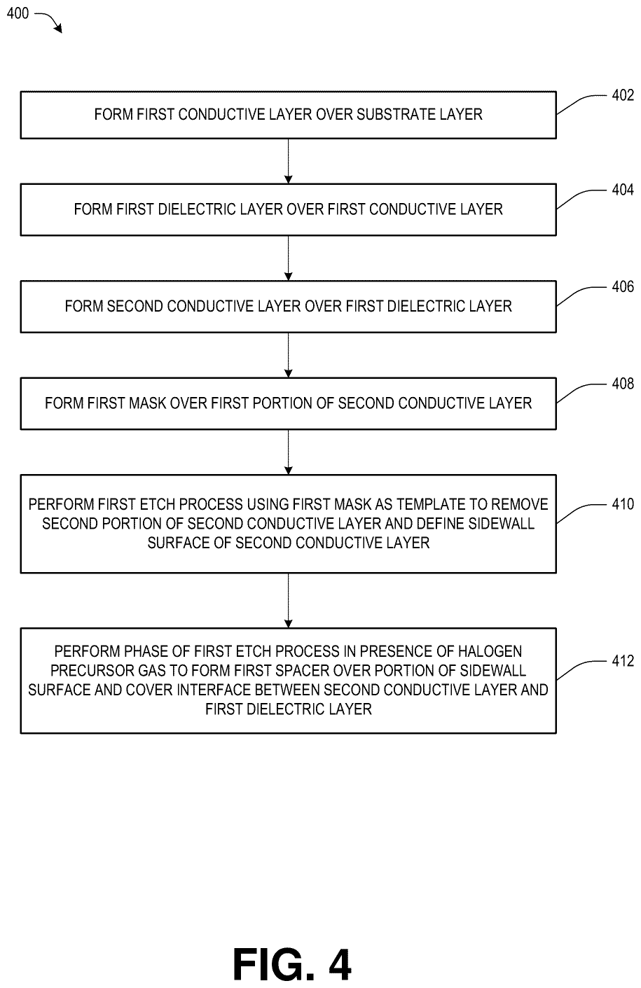

FIG. 4 is a flow diagram illustrating a method 400 for forming a semiconductor arrangement 100, in accordance with some embodiments. At 402, a first conductive layer 215A is formed over a substrate layer 205. At 404, a first dielectric layer 220A is formed over the first conductive layer 215A. At 406, a second conductive layer 215B is formed over the first dielectric layer 220A. At 408, a first mask 360 is formed over a first portion of the second conductive layer 215B. At 410, a first etch process is performed using the first mask 360 as an etch template to remove a second portion of the second conductive layer 215B and define a sidewall surface 265 of the second conductive layer 215B. At 412, a phase of the first etch process is performed in the presence of a halogen precursor gas to form a first spacer 370 over a portion of the sidewall surface 265 and cover a corner interface 375 between the second conductive layer 215B and the first dielectric layer 220A.

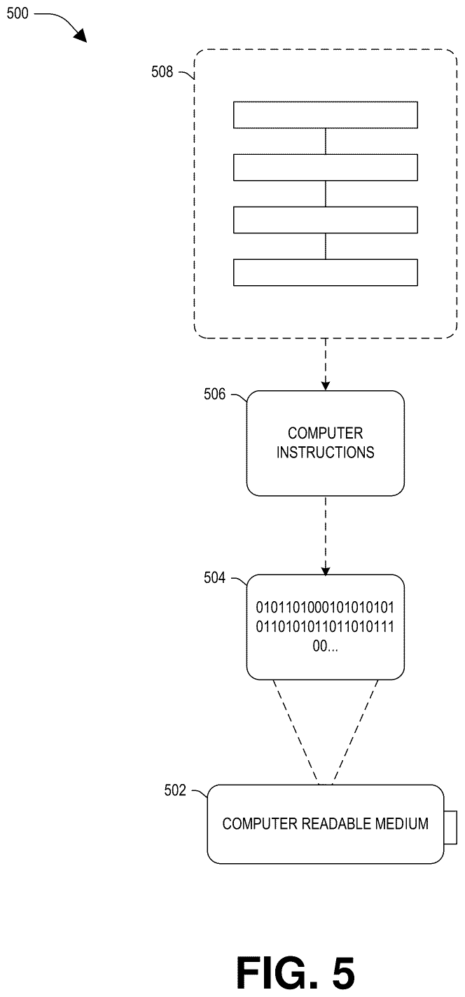

Still another embodiment involves a computer-readable medium comprising processor-executable instructions configured to implement one or more of the techniques presented herein. An exemplary computer-readable medium is illustrated in FIG. 5, wherein the embodiment 500 comprises a computer-readable medium 502 (e.g., a CD-R, DVD-R, flash drive, a platter of a hard disk drive, etc.), on which is encoded computer-readable data 504. This computer-readable data 504 in turn comprises a set of processor-executable computer instructions 506 configured to operate according to one or more of the principles set forth herein. In some embodiments 500, the processor-executable computer instructions 506 are configured to perform a method 508, such as at least some of the aforementioned methods. In some embodiments, the processor-executable computer instructions 506 are configured to implement a system, such as at least some of the aforementioned systems. Many such computer-readable media may be devised by those of ordinary skill in the art that are configured to operate in accordance with the techniques presented herein.

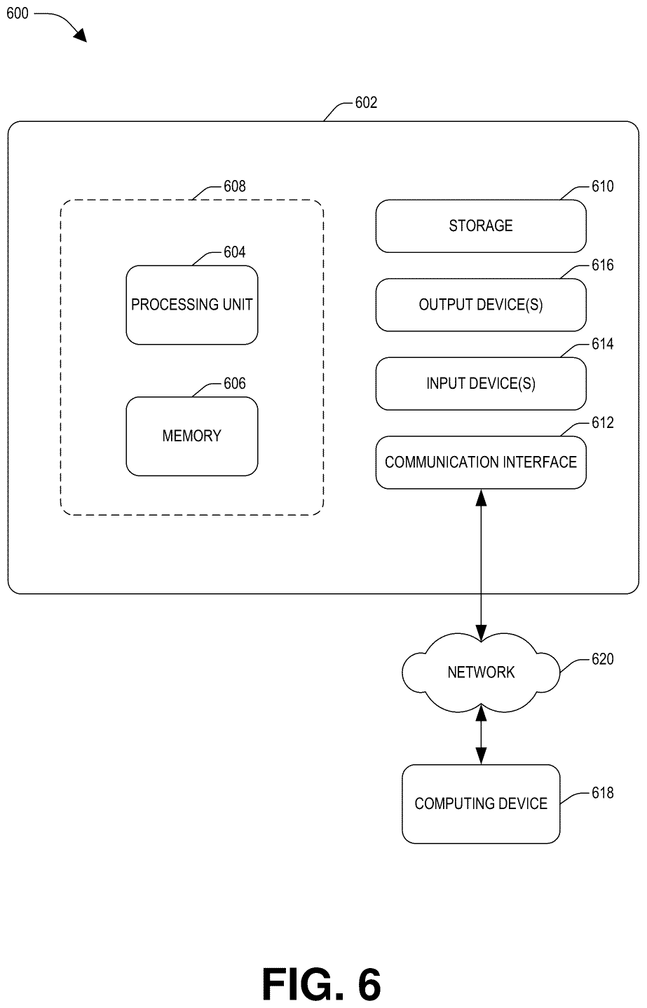

FIG. 6 and the following discussion provide a brief, general description of a suitable computing environment to implement embodiments of one or more of the provisions set forth herein. The operating environment of FIG. 6 is only one example of a suitable operating environment and is not intended to suggest any limitation as to the scope of use or functionality of the operating environment. Example computing devices include, but are not limited to, personal computers, server computers, hand-held or laptop devices, mobile devices (such as mobile phones, Personal Digital Assistants (PDAs), media players, and the like), multiprocessor systems, consumer electronics, mini computers, mainframe computers, distributed computing environments that include any of the above systems or devices, and the like.

Although not required, embodiments are described in the general context of “computer readable instructions” being executed by one or more computing devices. Computer readable instructions may be distributed via computer readable media (discussed below). Computer readable instructions may be implemented as program modules, such as functions, objects, Application Programming Interfaces (APIs), data structures, and the like, that perform particular tasks or implement particular abstract data types. Typically, the functionality of the computer readable instructions may be combined or distributed as desired in various environments.

FIG. 6 depicts an example of a system 600 comprising a computing device 602 to implement some embodiments provided herein. In some configurations, the computing device 602 includes at least one processing unit 604 and memory 606. Depending on the exact configuration and type of computing device, the memory 606 may be volatile (such as random access memory (RAM), for example), non-volatile (such as read-only memory (ROM), flash memory, etc., for example) or some combination of the two. This configuration is illustrated in FIG. 7 by dashed line 608.

In some embodiments, the computing device 602 may include additional features and/or functionality. For the example, the computing device 602 may also include additional storage (e.g., removable and/or non-removable) including, but not limited to, magnetic storage, optical storage, and the like. Such additional storage is illustrated in FIG. 6 by storage 610. In some embodiments, computer readable instructions to implement one or more embodiments provided herein may be in the storage 610. The storage 610 may also store other computer readable instructions to implement an operating system, an application program, and the like. Computer readable instructions may be loaded in the memory 606 for execution by the at least one processing unit 604, for example.

The term “computer readable media” as used herein includes computer storage media. Computer storage media includes volatile and nonvolatile, removable and non-removable media implemented in any method or technology for storage of information such as computer readable instructions or other data. The memory 606 and storage 610 are examples of computer storage media. Computer storage media includes, but is not limited to, RAM, ROM, electrically erasable programmable read-only memory (EEPROM), flash memory, or other memory technology, CD-ROM, Digital Versatile Disks (DVDs) or other optical storage, magnetic cassettes, magnetic tape, magnetic disk storage, or other magnetic storage devices, or any other medium which can be used to store the desired information and which can be accessed by the computing device 602. Any such computer storage media may be part of the computing device 602.

In some embodiments, the computing device 602 comprises a communication interface 612, or multiple communication interfaces, that allow the computing device 602 to communicate with other devices. The communication interface 612 may include, but is not limited to, a modem, a Network Interface Card (NIC), an integrated network interface, a radio frequency transmitter/receiver, an infrared port, a Universal Serial Bus (USB) connection, or other interface for connecting the computing device 602 to other computing devices. The communication interface 612 may implement a wired connection or a wireless connection. The communication interface 612 may transmit and/or receive communication media.

The term “computer readable media” may include communication media. Communication media typically embodies computer readable instructions or other data in a “modulated data signal” such as a carrier wave or other transport mechanism and includes any information delivery media. The term “modulated data signal” may include a signal that has one or more of its characteristics set or changed in such a manner as to encode information in the signal.

The computing device 602 may include input device(s) 614 such as keyboard, mouse, pen, voice input device, touch input device, infrared cameras, video input devices, and/or any other suitable input device. An output device(s) 616 such as one or more displays, speakers, printers, and/or any other suitable output device may also be included in the computing device 602. The input device(s) 614 and the output device(s) 616 may be connected to the computing device 602 via a wired connection, wireless connection, or any combination thereof. In some embodiments, an input device or an output device from another computing device may be used as the input device(s) 614 or the output device(s) 616 for the computing device 602.

Components of the computing device 602 may be connected by various interconnects, such as a bus. Such interconnects may include a Peripheral Component Interconnect (PCI), such as PCI Express, a USB, firewire (IEEE 1394), an optical bus structure, and the like. In some embodiments, components of the computing device 602 may be interconnected by a network. For example, the memory 606 may be comprised of multiple physical memory units located in different physical locations interconnected by a network.

Those skilled in the art will realize that storage devices utilized to store computer readable instructions may be distributed across a network. For example, a computing device 618 accessible via a network 620 may store computer readable instructions to implement one or more embodiments provided herein. The computing device 602 may access the computing device 618 and download a part or all of the computer readable instructions for execution. Alternatively, the computing device 602 may download pieces of the computer readable instructions, as needed, or some instructions may be executed at the computing device 602 and some instructions may be executed at the computing device 618.

Providing the spacer 310, 340, 370 over interfaces between conductive layers 215A, 215B, 215C, 215D and dielectric layers 220A, 220B, 220C, 220D when performing mask removal and cleaning processes protects the dielectric layers 220A, 220B, 220C, 220D from erosion. Reducing erosion of the dielectric material of the dielectric layers 220A, 220B, 220C, 220D reduces leakage current, increases capacitance of the capacitor, and reduces defects in the capacitor, such as a short between conductive layers.

According to some embodiments, a method of forming a semiconductor arrangement includes forming a first conductive layer over a substrate layer. A first dielectric layer is formed over the first conductive layer. A second conductive layer is formed over the first dielectric layer. A first mask is formed over a first portion of the second conductive layer. A first etch process is performed using the first mask as a template to remove a second portion of the second conductive layer and define a sidewall surface of the second conductive layer. Performing the first etch process includes comprises performing a phase of the first etch process in the presence of a halogen precursor gas to form a first spacer over a portion of the sidewall surface and cover an interface between the second conductive layer and the first dielectric layer.

According to some embodiments, a semiconductor arrangement includes a first conductive layer and a first dielectric layer over the first conductive layer. A second conductive layer is over a portion of the first dielectric layer and has a sidewall surface. A spacer is over a portion of the sidewall surface of the second conductive layer and covers an interface between the second conductive layer and the first dielectric layer. The first conductive layer, the first dielectric layer, and the second conductive layer define a capacitor.

According to some embodiments, a capacitor includes a first metal layer comprising a first metal, a second metal layer, a first dielectric layer between the first metal layer and the second metal layer, and a spacer comprising a metal halide. The metal halide comprises the first metal. The spacer covers an interface between the first dielectric layer and the first metal layer or the second metal layer.

The foregoing outlines features of several embodiments so that those of ordinary skill in the art may better understand various aspects of the present disclosure. Those of ordinary skill in the art should appreciate that they may readily use the present disclosure as a basis for designing or modifying other processes and structures for carrying out the same purposes and/or achieving the same advantages of various embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc., depicted herein are illustrated with particular dimensions relative to one another, such as structural dimensions or orientations, for example, for purposes of simplicity and case of understanding and that actual dimensions of the same differ substantially from that illustrated herein, in some embodiments. Additionally, a variety of techniques exist for forming the layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A method of forming a semiconductor arrangement, comprising:
forming a first dielectric layer;
forming a first conductive layer over the first dielectric layer;
forming a first mask over a first portion of the first conductive layer; and
performing a first etch process using the first mask as an etch template to remove a second portion of the first conductive layer and define a sidewall surface of the first conductive layer, wherein:
performing the first etch process comprises performing a phase of the first etch process in the presence of a halogen precursor gas to form a first spacer over a portion of the sidewall surface of the first conductive layer and cover an interface between the first conductive layer and the first dielectric layer.

2. The method of claim 1, comprising:
performing a process to remove the first mask in the presence of the first spacer.

3. The method of claim 1, comprising:
forming a second dielectric layer over the first conductive layer prior to forming the first mask; and
performing the first etch process using the first mask as an etch template to remove a portion of the second dielectric layer and define a sidewall surface of the second dielectric layer, wherein the first spacer covers the sidewall surface of the second dielectric layer.

4. The method of claim 3, wherein first spacer covers an interface between the second dielectric layer and the first conductive layer.

5. The method of claim 1, comprising:
forming a second conductive layer over a second dielectric layer, wherein forming the first dielectric layer comprises forming the first dielectric layer over the second conductive layer;
forming a second mask over a first portion of the first dielectric layer and a first portion of the second conductive layer after performing the first etch process; and
performing a second etch process using the second mask as an etch template to remove a second portion of the first dielectric layer, to remove a second portion of the second conductive layer and define a sidewall surface of the second conductive layer, and to expose the second dielectric layer, wherein:
performing the second etch process comprises performing a phase of the second etch process in the presence of a second halogen precursor gas to form a second spacer over a portion of the sidewall surface of the second conductive layer and cover an interface between the second conductive layer and the second dielectric layer.

6. The method of claim 5, wherein:
performing the second etch process using the second mask as an etch template to remove the second portion of the first dielectric layer comprises removing the second portion of the first dielectric layer to define a sidewall surface of the first dielectric layer, and
the second spacer covers the sidewall surface of the first dielectric layer.

7. The method of claim 5, comprising:
performing a process to remove the second mask in the presence of the first spacer and the second spacer.

8. The method of claim 5, wherein forming the second mask comprises forming the second mask over the first spacer.

9. The method of claim 1, wherein the first spacer comprises a metal halide.

10. The method of claim 1, wherein the first conductive layer comprises titanium nitride.

11. The method of claim 1, wherein the halogen precursor gas comprises at least one of fluoride, chloride, or bromide.

12. A method of forming a semiconductor arrangement, comprising:
forming a first conductive layer;
forming a first dielectric layer over the first conductive layer;
forming a mask over a first portion of the first dielectric layer; and
performing an etch process using the mask as an etch template to remove a second portion of the first dielectric layer and a first portion of the first conductive layer and to form a first spacer adjacent a second portion of the first conductive layer and the first portion of the first dielectric layer.

13. The method of claim 12, wherein performing the etch process to form the first spacer comprises performing the etch process to form the first spacer adjacent the mask.

14. The method of claim 12, comprising:
performing a process to remove the mask and expose a surface of the first spacer adjacent the mask prior to the mask being removed.

15. The method of claim 12, wherein:
forming the first conductive layer comprises forming the first conductive layer on a second dielectric layer; and
performing the etch process comprises performing the etch process to expose the second dielectric layer.

16. The method of claim 15, wherein the first spacer covers an interface between the second dielectric layer and the first conductive layer.

17. A method of forming a semiconductor arrangement, comprising:
forming a first conductive layer;
forming a first dielectric layer over the first conductive layer;
forming a first spacer having a first sidewall contacting a sidewall of the first conductive layer and a sidewall of the first dielectric layer; and
forming a second dielectric layer over the first spacer, wherein the second dielectric layer contacts the first sidewall of the first spacer and a second sidewall of the first spacer on a diametrically opposite side of the first spacer relative to the first sidewall.

18. The method of claim 17, comprising:
forming a via portion of an interconnect structure through the second dielectric layer and the first dielectric layer to contact the first conductive layer.

19. The method of claim 18, wherein forming the via portion comprises forming the via portion such that the via portion is spaced apart from the first sidewall of the first spacer by the second dielectric layer.

20. The method of claim 17, comprising:
forming a second conductive layer over the first dielectric layer; and
forming a second spacer contacting a sidewall of the second conductive layer prior to forming the second dielectric layer.
